(19) United States
(12) Patent Application Publication
(10) Pub. No.: US 2006/0140419 A1
(43) Pub. Date: Jun. 29, 2006

(54) Vacuum tube audio frequency power amplifier variable amplitude clipper

(76) Inventor: Samuel Irwin Timberlake JR., Vestavia Hills, AL (US)

Correspondence Address: SAMUEL IRWIN TIMBERLAKE, JR., 1901 POST OAK RD., VESTAVIA HILLS, AL, 35216, US

(21) Appl. No.: 11/024,113

(22) Filed: Dec. 28, 2004

(51) Int. Cl. H03G 9/00

(52) U.S. Cl. 381/102

(57) ABSTRACT

The Vacuum Tube Audio Frequency Power Amplifier Variable Amplitude Clipper provides a new method of varying vacuum tube power amplifier output power/volume to the loudspeaker. The amplitude at which power tube clipping occurs can be varied allowing one to take advantage of the inherent volume compression and output limiting at different volume levels. It reduces power tube plate voltage with minimal effect on preamp and driver tube voltage. Tone remains constant and the feel enhanced.

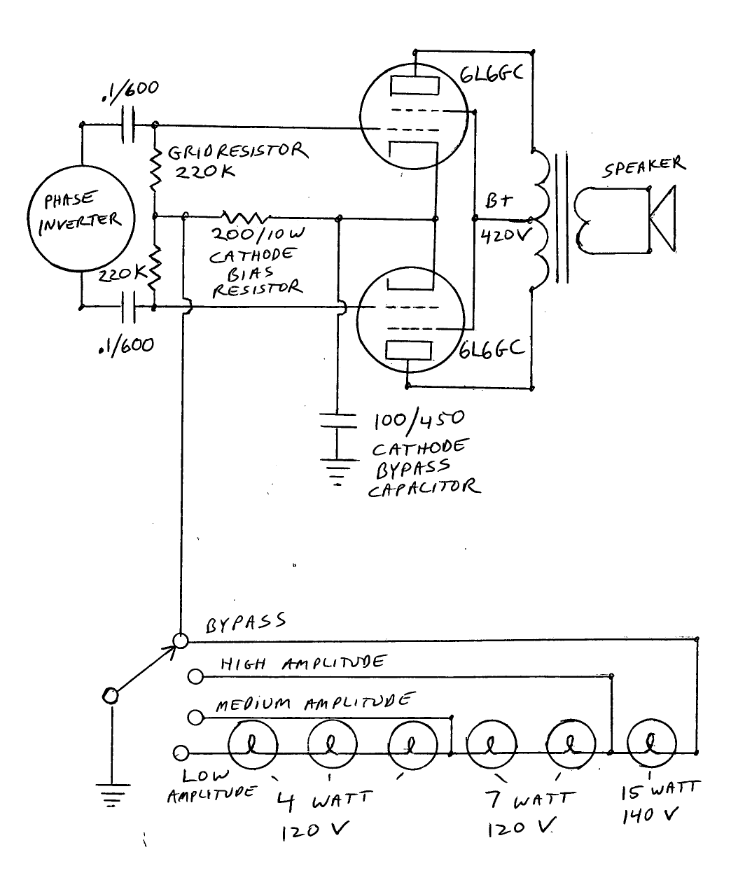

### CROSS REFERENCE TO RELATED APPLICATIONS

Not Applicable

### STATEMENT REGARDING FED SPONSORED R & D

Not Applicable

### REFERENCE TO A SEQUENCE LISTING, A TABLE, OR A COMPUTER PROGRAM LISTING APPENDIX

Not Applicable

### BACKGROUND OF THE INVENTION/SUMMARY OF THE INVENTION

The Vacuum Tube Audio Frequency Power Amplifier Variable Amplitude Clipper invention pertains to the manufacture of vacuum tube-type musical instrument amplifiers and the supply of kits for modification of existing vacuum tube-type musical instrument amplifiers. Musicians frequently take advantage of the inherent volume compression and output limiting that occurs when output tubes are driven to saturation (clipping). These conditions have desirable effects to tone and feel. This clipping only begins to occur at full power output. The full power amplitude may produce volume levels that are too high. The Vacuum Tube Audio Frequency Power Amplifier Variable Amplitude Clipper solves this problem by allowing the user to change volumes at which clipping occurs. The tone and feel are available at many desired volumes.

### DRAWING

The supplied drawing is a schematic diagram of the Vacuum Tube Audio Frequency Power Amplifier Variable Amplitude Clipper and a partial circuit of the prototype amplifier. Details are in the following Description.

### DETAILED DESCRIPTION OF THE INVENTION

The Vacuum Tube Audio Frequency Power Amplifier Variable Amplitude Clipper allows reduction of the amplitude at which high level clipping occurs in a vacuum tube power amplifier. The power tube cathode/s or cathode bias resistor is lifted above ground to reduce the effective power tube plate voltage and output amplitude while minimally affecting preamp and driver tube B+ voltages. This is different from circuits that lower overall B+. This circuit is unique because-incandescent lamps are used as ballast resistors to reduce power tube plate voltage and limit current. Lamps are chosen that incandesce at the same voltage as the reduction required. This is a balanced circuit where a higher wattage lamp will reduce voltage less than a lower wattage lamp. A typical 50-watt amplifier can use a 20-watt/100-volt lamp to reduce voltage approximately 100 volts. But a 10-watt/220-volt lamp will cause reduction of 200 volts or more. If a necessary lamp value is not available, standard lamps may be connected in series and/or parallel. A cathode bypass capacitor is utilized and always remains connected to ground. It must have a minimum DC rating equivalent to B+. The Vacuum Tube Audio Frequency Power Amplifier Variable Amplitude Clipper includes a switching system for use while the amplifier is on and if necessary when under load. A bypass setting may also be utilized.

Use of cathode bias with the Vacuum Tube Audio Frequency Power Amplifier Variable Amplitude Clipper requires the grid resistors to be switched with the cathode bias resistor when it is lifted above ground. If fixed bias is used, the correct grid resistor bias voltage must be switched simultaneously with each lamp connected to the cathode/s.

An example of the Vacuum Tube Audio Frequency Power Amplifier Variable Amplitude Clipper circuit is my prototype amplifier with push/pull 6L6GC output tubes and 420 volts B+ (plate to cathode). See included drawing. The cathode bias resistor is a typical 200-ohm 10-watt. The switching system “bypass” setting connects this resistor as well as the grid resistors to ground. The “high amplitude” setting lifts the cathode bias resistor and grid resistors above ground through a 15-watt 140-volt lamp, reducing the plate voltage to 295 volts. The cathode bypass capacitor remains connected to ground. The “medium amplitude” setting lifts the 15-watt lamp and resistors above ground connecting them in series with two series connected 7-watt 120-volt lamps. The 7-watt lamps incandesce and reduce the plate voltage to 170 volts. The “low amplitude” setting lifts the 7-watt lamps, 15-watt lamp; and resistors above ground connecting them in series with three series connected 4-watt 120-volt lamps. The 4-watt lamps incandesce and lower plate voltage to 100 volts. With each setting the power tube plate voltage is reduced and the amplitude at which saturation and clipping occurs is also reduced.

This invention will be used in the manufacture of vacuum tube type Variable Amplitude Clipping amplifiers and in kits for retrofitting existing vacuum tube type amplifiers. It is suitable for use in push/pull and single sided designs.

1. What I claim as my invention, the Vacuum Tube Audio Frequency Power Amplifier Variable Amplitude Clipper, is the use of incandescent lamps and a switching system to vary the amplitude of clipping in a vacuum tube audio frequency power amplifier while it is on and if necessary under load.
